(19) United States
(12) Patent Application Publication
(10) Pub. No.: US 2008/0301370 A1
(43) Pub. Date: Dec. 4, 2008

(54) Memory Module

(75) Inventors: Srdjan Djordjevic, Munchen (DE); Hermann Ruckerbauer, Moos (DE); Maurizio Skerlj, Munchen (DE); Christian Mueller, Worth (DE)

Correspondence Address: EDELL, SHAPIRO & FINNAN, LLC, 1901 RESEARCH BLVD., SUITE 400, ROCKVILLE, MD, 20850, US

(73) Assignee: QIMONDA AG, Munich (DE)

(21) Appl. No.: 11/757,770

(22) Filed: Jun. 4, 2007

(51) Int. Cl. G06F 12/00; G06F 13/00; H03F 21/00

(52) U.S. Cl. 711/127; 330/1 R; 710/104

(57) ABSTRACT

A memory module includes a module circuit board, an amplifier circuit disposed on the module circuit board for amplifying an input signal, and a memory component to store a data item, wherein the memory component is disposed on the module circuit board. The amplifier circuit includes an input to receive a data signal and an output to provide an amplified data signal. The memory component comprises an input to receive the amplified data signal, wherein the data item is stored in the memory component in dependence on a level of the received amplified data signal.

### BACKGROUND

Modern memory modules, such as Dual In-Line Memory Modules (DIMMs), can benefit from architectures that permit faster operation. In particular, it is desirable to reduce the load occurring at input terminals of memory components receiving address, clock, and data signals in order to permit the memory controller to run faster.

### BRIEF DESCRIPTION OF THE DRAWINGS

Exemplary embodiments of the invention are described in connection with the following drawings, where like reference numerals in the various figures are utilized to designate like components.

FIG. 1 shows an embodiment of a system topology wherein a memory controller is connected to memory modules.

FIG. 2 shows an embodiment of an amplifier circuit to amplify data and address signals.

FIG. 3 shows an embodiment of a top and bottom surface of a memory module comprising a bus structure to transfer address signals to amplifier circuits.

FIG. 4 shows an embodiment of a top and bottom surface of a memory module comprising a bus structure to transfer amplified address signals to memory components.

FIG. 5 shows an embodiment of a top and bottom surface of a memory module comprising a bus structure to transfer data signals to amplifier circuits to amplify the data signals.

FIG. 6 shows an embodiment of a top and bottom surface of a memory module comprising a bus structure to transfer amplified data signals to memory components.

FIG. 7 shows a further embodiment of a top and bottom surface of a memory module comprising a bus structure to transfer amplified data signals to memory components.

FIG. 8 shows an embodiment of a memory system.

### DETAILED DESCRIPTION

A memory module comprises a module circuit board wherein memory components are generally disposed on a top and bottom surface of the memory module. Each of the memory components contains one or more memory chips comprising memory cells to store data items. Read and write accesses to the memory cells are carried out synchronously to a clock signal which is applied to the memory module. In order to select a memory cell of the memory components, address signals are applied to the memory module. If a memory cell is selected by an address signal, a data item is written in the selected memory cell in dependence on a data signal applied to the memory module. In case of a read access, a data item of a memory cell selected by an address is read out of the selected memory cell.

In a configuration 4R×4, 18 memory chips per rank are distributed on the surfaces of the memory module. Therefore, a configuration of 4R×4 comprises altogether 72 memory chips. If nine memory components are respectively disposed on the top and the bottom surface of the memory module, each of the memory components comprises four memory chips in a stacked configuration. In a configuration 8R×8 of the memory module, a rank comprises nine memory chips. Accordingly, in a configuration of 8R×8 also 72 memory chips are distributed on the top and bottom surface of the memory module.

In order to transfer data signals from external connectors of the memory module to the memory components to write in data items and to transfer data signals from the memory components to the external connectors of the memory module to read out data items, the memory components are connected to the external connectors via data buses. In dependence on a number of memory components arranged on the module circuit board, the load which is connected to the data bus may be very high. A high load connected to a bus generally reduces the speed by which signals may be transferred via the bus.

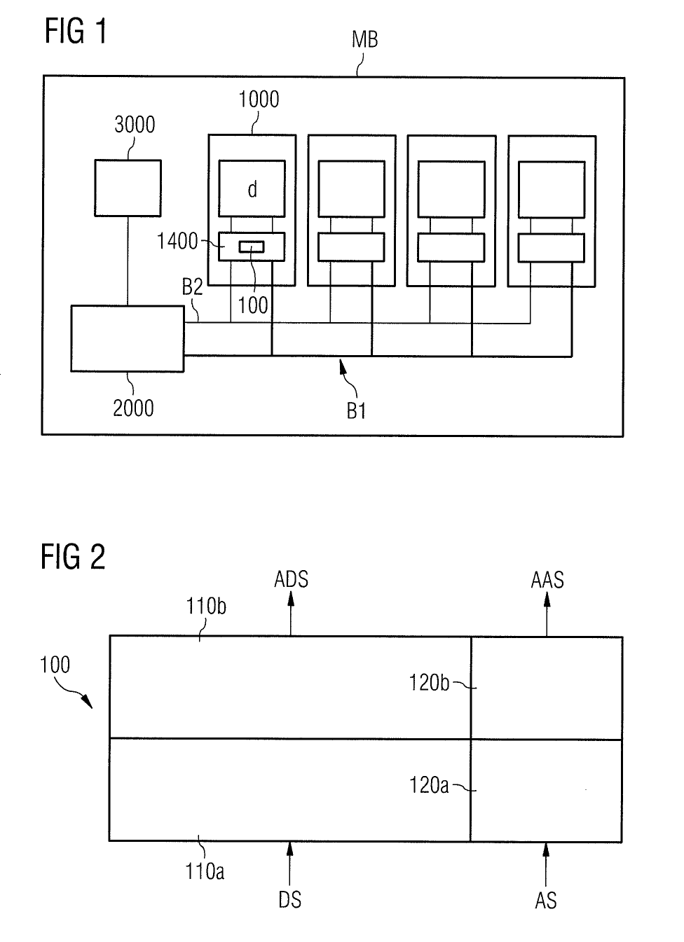

FIG. 1 shows a system topology wherein a control component 2000, for example a memory controller, is connected to four memory modules 1000. The memory modules are disposed on a motherboard MB of a computer system 4000. The memory controller 2000 is connected to a microprocessor 3000. The memory modules are build for example as DIMMs (Dual In-Line Memory Modules). Each of the memory modules is connected to the control circuit 2000 via a bus B1 and a bus B2. The bus B1 is adapted to transfer signals, such as data signals, between control circuit 2000 and each of the memory modules 1000 (DQ-Bus). Bus B2 is adapted to transfer signals, such as address signals, from control circuit 2000 to the memory modules 1000 (CA-Bus).

Each of the memory modules 1000 comprises memory chips, for example DRAM (dynamic random access memory) chips, with memory cells to store data items. A signal, such as a data signal, is not directly transferred from the control circuit 2000 to a memory component of a memory module 1000. In an embodiment of the memory module, the data signal generated by the memory controller is transferred via bus B1 to a buffer circuit 1400 to buffer the received signals. The buffer circuit 1400 also comprises an amplifier circuit 100 which amplifies the received data signal. After amplification of the data signal, amplifier circuit 100 redrives the amplified data signal to a selected memory component d of the memory module. The data signal transmitted by the memory controller 2000 is amplified, but not compressed or changed into another data format. The amplifier circuit 100 outputs an output signal which has the same structure as the input signal but has a higher amplitude due to the amplification.

In another embodiment of the memory module, an address signal generated by the control circuit 2000 is transferred to amplifier circuit 100 to amplify the address signal. After amplification of the received address signal, amplifier circuit 100 redrives the amplified address signal to one of the memory components d. Except for an amplification of the address signal, the input address signal is not changed by the amplifier circuit, for example it is not changed into another data format by amplifier circuit 100.

The amplified data and/or address signals are transferred to the memory components d by different bus structures dependent on the kind of the amplified signal. In the same way, as described for the address and the data signals, in another embodiment of the memory module, also a clock signal which is generated by memory controller 2000 is amplified by amplifier circuit 100 and transferred to the memory components to synchronously control read and write accesses.

The buffering, amplifying and redriving of signals by buffer circuit 1400 and amplifier circuit 100 reduces the load occurring at input terminals of the memory components for receiving address, clock and data signals. The memory controller just drives an input of a buffer/amplifier circuit. However, the amplifier circuit redrives a larger number of loads, for example 8/9 or 16/18 or 32/36 or 64/72 or 128/144 loads, such as DRAM memory components, dependent on a configuration of the memory module. Buffering and redriving of clock, address and data signals allows the memory controller 2000 to run faster.

In FIGS. 2 to 7 embodiments of a memory module are shown wherein data and/or address signals are buffered and amplified before redriving the signals to memory components. For reasons of better illustration buffer circuit 1400 is not shown in FIGS. 2 to 7. As illustrated in FIG. 2, amplifier circuit 100 which may be included in a buffer circuit, as exemplarily shown in FIG. 1, comprises an input 110a for receiving data signals DS which are generated, for example, by a memory controller. After buffering and amplifying the data signals, amplified data signals ADS are provided at an output 110b of amplifier circuit 100. Furthermore, amplifier circuit 100 comprises an input 120a for receiving address signals AS. After buffering and amplifying the received address signals, amplifier circuit 100 generates amplified address signals AAS at an output 120b.

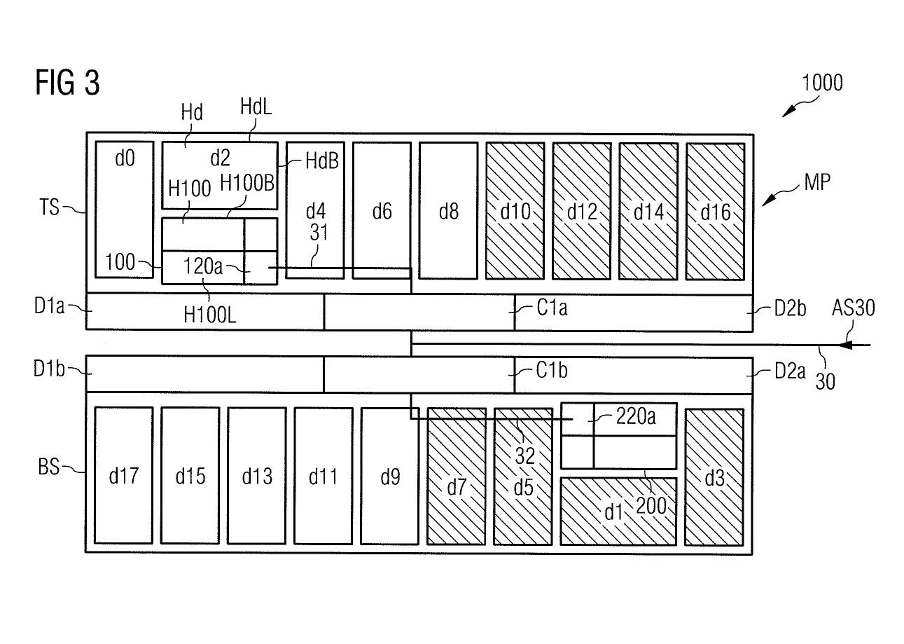

FIG. 3 shows a top surface TS and a bottom surface BS of the memory module 1000. The top and bottom surface of the memory module comprises connectors D1a, D1b located on the left side of the module circuit board and connectors D2a and D2b located on the right side of the module circuit board MP, respectively to apply data signals. Connectors C1a and C1b to apply address signals are disposed between the connectors D1a and D1b on the top surface of the module circuit board and between connectors D1b and D2b on the bottom surface of the module circuit board. Furthermore, FIG. 3 shows an address bus 30 connected to a memory controller to transfer address signals AS30 to the memory module 1000. Address bus 30 is connected to connectors C1a and C1b to apply the address signals. An address bus 31 connected to connectors C1a transfers the applied address signals to an input 120a of amplifier circuit 100 located on the top surface on the module circuit board. An address bus 32 connects the input 220a of amplifier circuit 200 located on the bottom surface of the module circuit board to connectors C1b.

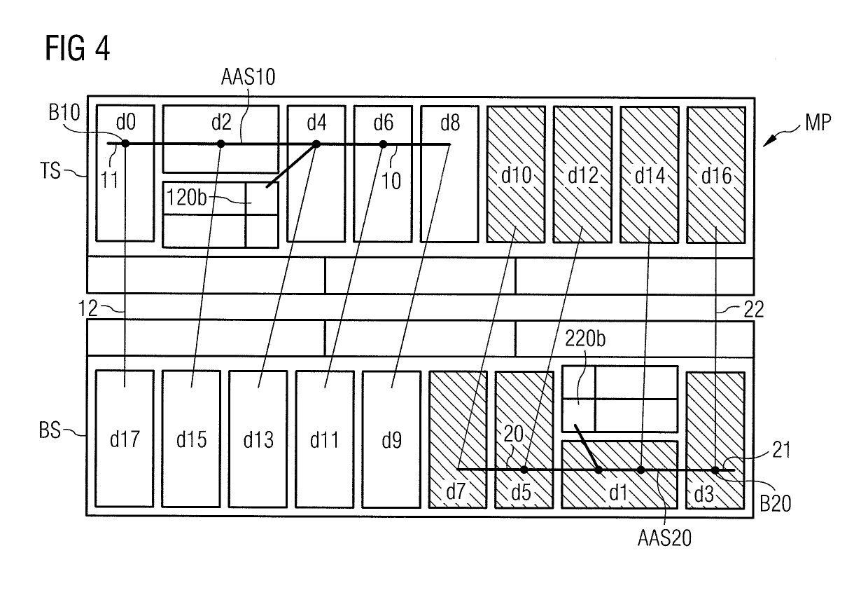

FIG. 4 shows the routing for address buses 10 and 20 to transfer the amplified address signal AAS10 and AAS20 amplified by amplifier circuits 100 and 200 to respective memory components. Address bus 10 is connected to the output 120b of amplifier circuit 100 and transfers the amplified address signal AAS 10 which corresponds to the address signal AS30 after amplification by amplifier circuit 10 to memory components d0, d2, d4, d6 and d8 located on the top surface TS of the module circuit board and to memory components d9, d11, d13, d15 and d17 located on the bottom surface BS of the module circuit board. Address bus 20 connects output 220b of amplifier circuit 200 to memory circuit components d1, d3, d5 and d7 located on the bottom surface of module circuit board MP and to memory components d10, d12, d14 and d16 arranged on the top surface TS of module circuit board MP.

According to an embodiment of the memory module, an odd number of memory components is respectively connected to each of the address buses 10 and 20. Each of the address buses 10 and 20 comprises branching nodes B10, B20 at which the main bus branches in bus sections 11 and 12 for address bus 10 and bus sections 21 and 22 for address bus 20. The bus sections are respectively connected to one of the memory components. The symmetrical connection of memory components to the address buses allows high signal integrity properties of the address bus. The post amplifier address bus (CA-bus) routing can be implemented as a non-terminated tree topology, as shown in FIG. 4, or as an end-terminated fly-by topology.

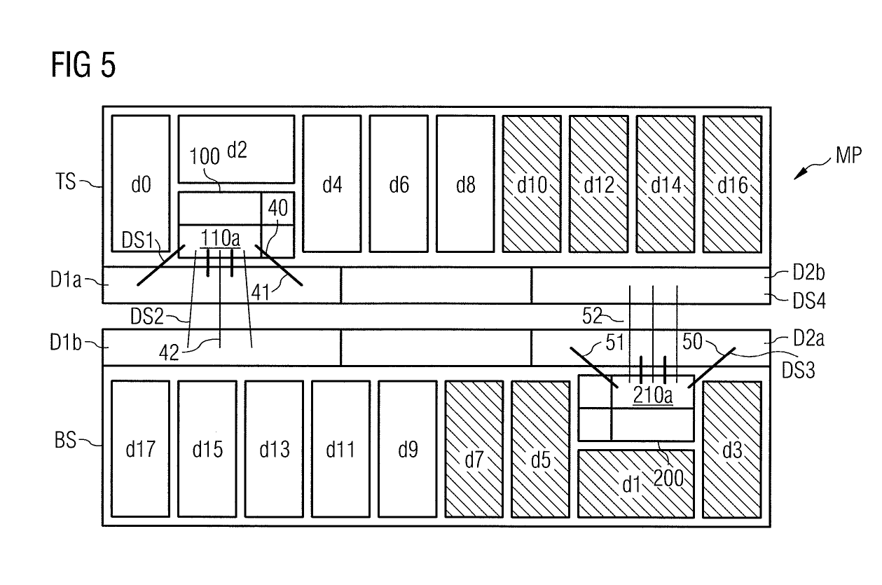

FIG. 5 shows a pre-amplifier routing of data bus 40 and 50 to transfer data signals between connectors D1a, D1b and amplifier circuit 100, and between connectors D2a, D2b and amplifier circuit 200 for a read and write access. For example, in case of a write access, data signals DS1 applied to connectors D1a to apply data signals are transferred to an input 110a of amplifier circuit 100 via data bus lines or stubs 41 of data bus 40. In the same way, connectors D1b arranged on the bottom surface of the module circuit board to apply data signals DS2 are connected by data bus lines or stubs 42 to the input 110a of amplifier circuit 100. Connectors D2a located on the bottom surface BS of the module circuit board MP are connected via data bus lines or stubs 51 of data bus 50 to the input 210a of amplifier circuit 200. In the same way, connectors D2b for applying data signals DS4 are connected via data bus lines or stubs 52 to the input 210a of amplifier circuit 200. After having received data signals DS1, DS2 or DS3, DS4, each of the amplifier circuits 100 and 200 amplifies the received data signal after buffering the data signal by a buffer circuit and provides the amplified data signal at an output of the respective amplifier circuit.

As illustrated in FIG. 5, amplifier circuits 100 and 200 are provided on opposite surfaces of the module circuit board MP. Providing more than one amplifier circuit allows the use of short stubs or bus lines for transferring data signals from connectors to respective input terminals of amplifier circuits 100 and 200. Therefore, amplifier circuits 100 and 200 are located in a near distance in relation to the connector area D1a, D1b, D2a and D2b. A module circuit board with short stubs or bus lines between data signal connectors and input terminals of amplifier circuits allows to realize the memory module with a high signal integrity and consequently a high speed on the data bus.

In the embodiment shown in FIG. 5, amplifier circuit 100 is coupled to 10 memory components on the left side of the module circuit board and amplifier circuit 200 is coupled to 8 memory components on the right side of the module circuit board. It is possible to use amplifier circuits with the same structure for both of the amplifier circuits, for example, amplifier circuits may be used respectively comprising 72 input terminals, wherein 40 input terminals of amplifier circuit 100 are used for receiving data signals to be transferred to memory components d0, d2, d4, d6, d8, d9, d11, d13, d5 and d17 located on the left side of the module circuit board, and 32 input terminals of amplifier circuit 200 are used for receiving data signals to be transferred to memory components d1, d3, d5, d7, d10, d12, d14 and d16 located on the right side of the module circuit board. In this embodiment, the remaining 32 or 42 input terminals of amplifier circuits 100 or 200 are unused.

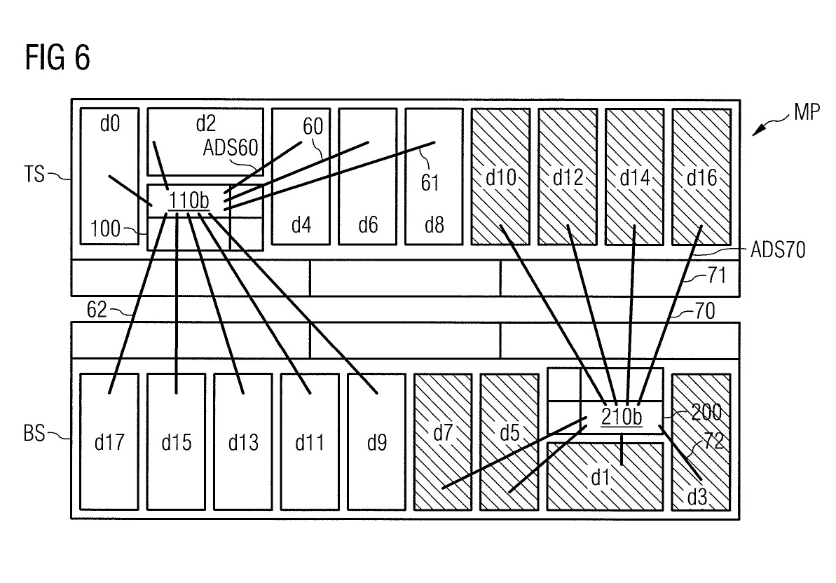

FIG. 6 illustrates a post-amplifier routing for a data bus 60 for transferring amplified data signals ADS60 between the amplifier circuit 100 and memory components d0, d2, d4, d6, d8, d9, d11, d13, d15 and d17 and for a data bus 70 for transferring amplified data signals ADS70 between amplifier circuit 200 and memory components d1, d3, d5, d7, d10, d12, d14 and d16 for a read and write access. Data bus 60 connects memory components on the left side of the module circuit board to the output 110b of amplifier circuit 100. The output 110b of amplifier circuit 100 is connected by respective data bus lines 61 of data bus 60 to each of the memory components d0, d2, d4, d6 and d8 arranged on the top surface of the module circuit board MP and by respective bus lines 62 of data bus 60 to memory components d9, d11, d13, d15 and d17 arranged on the bottom surface BS of module circuit board MP.

After buffering the received data signals DS1 and DS2, amplifier circuit 100 generates the amplified data signals ADS60 which are transferred to memory components d0, . . . , d8 and d9, . . . , d17. The output 210b of amplifier circuit 200 is connected via data bus lines 72 of data bus 70 to memory components d1, d3, d5 and d7 arranged on the bottom surface of module circuit board MP and via bus lines 71 of data bus 70 to memory components d10, d12, d14 and d16 arranged on the top surface of module circuit board MP. After buffering the received data signals, amplifier circuit 200 provides the amplified data signals ADS70 at the output 210b. The amplified data signals ADS70 are transferred to memory components d1, . . . , d7 and d10, . . . , d16, arranged on the right side of the module circuit board. Data items are stored in the memory components d0, . . . , d17 in dependence on a level of the amplified data signals ADS60 and ADS70. If an amplified data signal is transferred to a memory component via one of the data bus lines of data busses 60 or 70, for example, with a level below 0.75 V, the data item is stored in the memory component with a “0”-state, and is stored with a “1”-state, if the amplified data signal has a level above 0.75 V.

FIG. 6 illustrates the post-amplifier routing for data signals for a memory module, for example a DIMM in a configuration 4R×4. In this configuration of the DIMM, four memory chips are arranged in each of the memory components in a quad-stacked configuration.

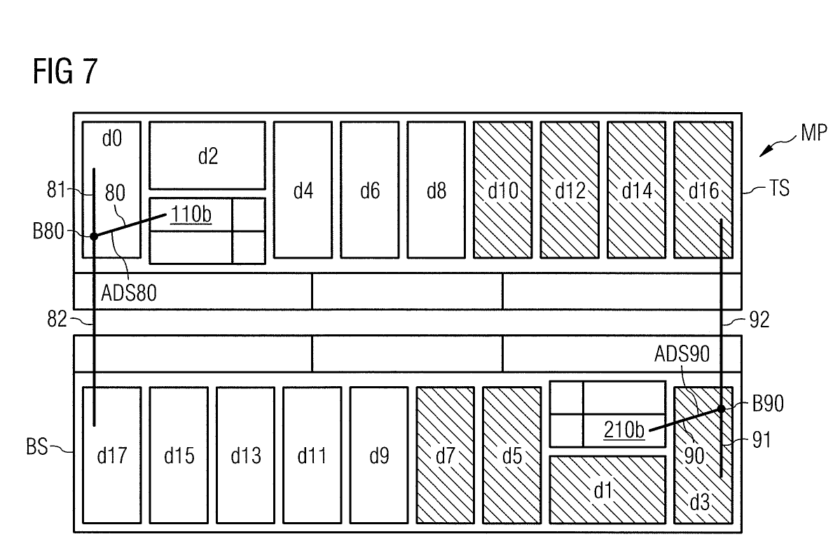

FIG. 7 illustrates a post-amplifier routing for amplified data signals ADS80 and ADS90 generated by amplifier circuits 100 and 200 after buffering and amplifying the received data signals DS1, . . . , DS4. Memory components are respectively connected to the respective output 110b and 210b of amplifier circuits 100 and 200 via data buses 80 and 90. As exemplarily shown for memory component d0 located on the top surface of module circuit board MP and memory component d17 located on the bottom surface of module circuit board MP, data bus 80 for transferring amplified data signals ADS80, which correspond to data signals DS1 or DS2 after amplification, branches at a branching node B80 in a data bus section 81 connected to memory component d0 and in a data bus section 82 connected to memory component d17. In the same way, data bus 90 to transfer amplified data signals ADS90, which correspond to data signals DS3 or DS4 after amplification, branches at the branching node B90 into data bus sections 91 connected to memory component d3 and data bus section 92 connected to memory component d1 6.

The arrangement of a data bus routing shown in FIG. 7 can be used for DIMMs in a configuration 8R×8 wherein memory chips are housed in the casings of memory components d0, . . . , d17 in a quad-stacked configuration.

The amplifier circuits 100 and 200 on the module circuit board can have the same dimensions in length and width as the memory components d0, . . . , d17. As illustrated in FIG. 3, amplifier circuit 100 is housed into a casing H100 and memory component d2 is housed into a casing Hd. Both of the casings have the same length H100L and HdL as well as the same width H100B and HdB. In contrast to the arrangement of memory components d0 and d3, . . . , d17, memory components d1 and d2 are arranged in a lengthwise direction above or under amplifier circuits 100 and 200 which are also disposed on the memory circuit board in a longitudinal direction.

Furthermore, the amplifier circuits are connected near the area of connectors D1a, D1b and D2a, D2b to apply the data signals which allows transferring signals with a high signal integrity and a high speed via the bus lines 40 and 50. Therefore, according to a preferred embodiment of the memory module, more than one amplifier circuit is provided, arranged on opposite surfaces of the module circuit board.

FIGS. 3 to 7 illustrate embodiments of registered memory modules. In contrast to the amplifier circuits 100 and 200 which only change the amplitude of applied data or address signals, a hubchip of an FBDIMM (filly buffered dual in-line memory module) changes the data format of the received data and address signals. Registered memory modules comprising amplifier circuits 100 and 200 for amplifying and redriving data and address signals have a lower current consumption than fully buffered memory modules.

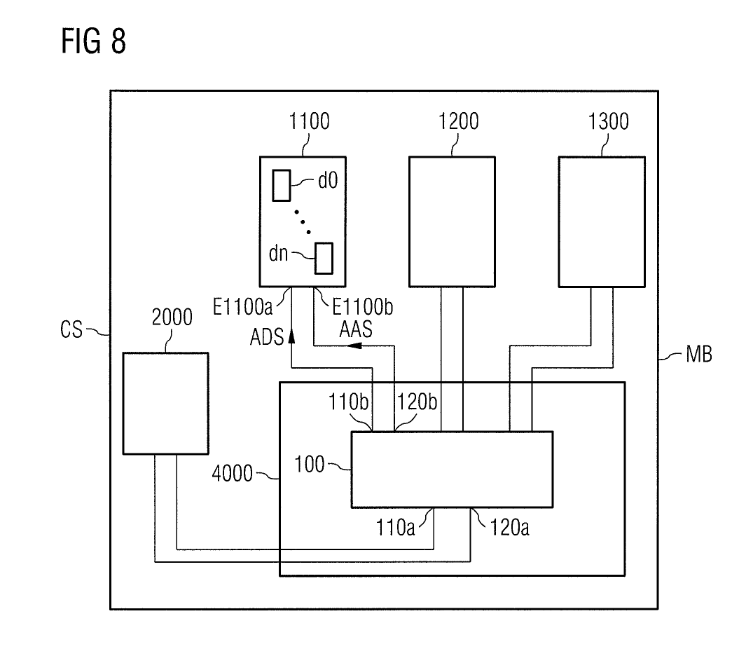

FIG. 8 shows a memory system comprising a plurality of memory subsystems 1100, 1200 and 1300. Each of the memory subsystems comprises memory components d0, . . . , dn to respectively store a data item. The memory system comprises a control circuit 2000 which may be formed as a memory controller. A buffer circuit 1400 is disposed between the memory subsystems and the control circuit 2000 to buffer signals received from the control circuit. The buffer circuit 1400 comprises an amplifier circuit 100. The control circuit 2000 generates a data signal DS which is transferred to an input 110a of amplifier circuit 100. After amplification of data signal DS, the amplified data signal ADS is output at an output 110b of the amplifier circuit 100 and is transferred to one of the memory subsystems 1100, 1200 and 1300 to store a data item in the selected one of the memory subsystems.

In another embodiment of the memory system, the control circuit 2000 generates an address signal AS which is transferred to an input 120a of the amplifier circuit 100. The address signal AS is amplified by the amplifier circuit 100 and the amplified address signal AAS is transferred to the memory subsystems 1100, 1200 and 1300. One of the memories is selected for a memory access in dependence on the amplified address signal ADS.

In another embodiment of the memory system, the control circuit 2000, the buffer circuit 1400 comprising the amplifier circuit 100 and the plurality of memory subsystems 1100, . . . , 1300 are disposed on a printed circuit board MB. The printed circuit board may be used as a motherboard of a computer system CS and the control circuit 2000 may be included in a memory controller of the computer system.

While specific embodiments have been described in detail in the foregoing detailed description and illustrated in the accompanying drawings, those with ordinary skill in the art will appreciate that various modifications and alternatives to those details could be developed in the light of the overall teachings of the disclosure. Accordingly, the particular arrangements disclosed are meant to be illustrative only and not limiting as to the scope of the invention, which is to be given the full breadth of the appended claims and any and all equivalents thereof.

What is claimed is:

1. A memory module, comprising:
a module circuit board;
an amplifier circuit disposed on the module circuit board and configured to amplify a data signal to produce an amplified data signal; and
a memory component disposed on the module circuit board and configured to store a data item, wherein the memory component receives the amplified data signal, and stores the data item in dependence on a level of the amplified data signal.

2. The memory module according to claim 1, further comprising:
a data signal connector configured to receive the data signal;
an address signal connector configured to receive an address signal;
wherein the amplifier circuit is arranged closer to the data signal connector than to the address signal connector.

3. The memory module according to claim 1, wherein the amplifier circuit is encapsulated in a casing having a same length as a casing of the memory component.

4. The memory module according to claim 1, wherein the amplifier circuit is encapsulated in a casing having a same width as a casing of the memory component.

5. The memory module according to claim 1, wherein the data item is stored in the memory component in dependence on a voltage level of the amplified data signal.

6. A memory module, comprising:
a module circuit board having a first surface and a second surface located opposite to the first surface;
a first amplifier circuit disposed on the first surface of the memory circuit board and configured to amplify a first data signal to produce a first amplified data signal; and
a first memory component disposed on the first surface of the module circuit board and configured to store a data item in dependence on a level of the first amplified data signal; and
a second memory component disposed on the second surface of the module circuit board and configured to store a data item in dependence on a level of the first amplified data signal.

7. The memory module according to claim 6, further comprising:
a first connector disposed on the first surface of the module circuit board and configured to receive the first data signal; and
a second connector disposed on the second surface of the module circuit board and configured to receive a second data signal, wherein an input of the first amplifier circuit is connected to the first and second connector.

8. The memory module according to claim 6, further comprising:
a second amplifier circuit disposed on the second surface of the memory circuit board and configured to amplify an second data signal to produce a second amplified data signal;
a third memory component disposed on the first surface of the module circuit board and configured to store a data item in dependence on a level of the second amplified data signal; and
a fourth memory component disposed on the second surface of the module circuit board and configured to store a data item in dependence on a level of the second amplified data signal.

9. The memory module according to claim 8, further comprising:
a third connector disposed on the second surface of the module circuit board and configured to receive a third data signal; and
a fourth connector disposed on the first surface of the module circuit board and configured to receive a fourth data signal;
wherein an input of the second amplifier circuit is connected to the third and fourth connectors.

10. The memory module according to claim 8,
wherein the data item is stored in one of the first and second memory components in dependence on a voltage level of the first amplified data signal; and
wherein the data item is stored in one of the third and fourth memory components in dependence on a voltage level of the second amplified data signal.

11. A memory module, comprising:
a module circuit board;
an amplifier circuit disposed on a first surface of the memory circuit board and configured to amplify data signals to produce amplified data signals;
a plurality of first memory components disposed on the first surface of the module circuit board and configured to respectively store a data item in dependence on a level of a received one of the amplified data signals;
first connectors disposed on the first surface of the module circuit board and configured to apply data signals; and
a plurality of input bus lines configured to respectively transfer data signals, wherein each of the first connectors is connected via first ones of the plurality of input bus lines to the amplifier circuit.

12. The memory module according to claim 11, further comprising:
a plurality of data bus lines configured to respectively transfer the amplified data signals, wherein first ones of the plurality of data bus lines are respectively connected to one of the plurality of the first memory components.

13. The memory module according to claim 12, further comprising:
a plurality of second memory components disposed on the second surface of the module circuit board and configured to respectively store a data item in dependence on a level of a received one of the amplified data signals, wherein second ones of the plurality of data bus lines are respectively connected to one of the plurality of the second memory components.

14. The memory module according to claim 13, wherein the amplifier circuit amplifies an address signal to produce an amplified address signal, the memory module further comprising an address bus to transfer the amplified address signal, wherein:
the address bus comprises branching nodes;
the address bus branches at each of the branching nodes in a first and second bus section of the address bus; and
the first bus section of the address bus is connected to one of the plurality of first memory components and the second bus section of the address bus is connected to one of the plurality of second memory components.

15. The memory module according to claim 11, further comprising:
a plurality of second memory components disposed on the second surface of the module circuit board and configured to respectively store a data item in dependence on a level of a received one of the amplified data signals; and
a data bus coupled to the amplifier circuit and configured to transfer one of the amplified data signals, the data bus comprising a branching node, wherein the data bus branches at the branching node in a first and second bus section of the data bus;
wherein the first bus section of the data bus is connected to one of the plurality of first memory components and the second bus section of the data bus is connected to one of the plurality of second memory components.

16. The memory module according to claim 11, wherein a data item is stored in each of the plurality of the memory components in dependence on a voltage level of the received one of the amplified data signals.

17. The memory module according to claim 11, further comprising:
second connectors disposed on the second surface of the module circuit board and configured to apply data signals, wherein each of the second connectors is connected via second ones of the plurality of input bus lines to the amplifier circuit.

18. A memory system, comprising:
an amplifier circuit configured to amplify a data signal to produce an amplified data signal; and
a memory subsystem comprising a plurality of memory components, wherein each of the memory components is configured to store a data item in dependence on a level of the amplified data signal.

19. The memory system according to claim 18, wherein the amplifier circuit amplifies an address signal to produce an amplified address signal, and wherein the memory subsystem receives the amplified address signal.

20. The memory system according to claim 19, further comprising:
a control circuit configured to control a memory access to the memory subsystem, wherein the control circuit is configured to generate the data signal and the address signal.

21. The memory system according to claim 20, further comprising:
a printed circuit board, wherein the memory subsystem, the amplifier circuit, and the control circuit are disposed on the printed circuit board.

22. The memory system according to claim 21, wherein the printed circuit board is a motherboard of a computer system and the control circuit is included in a memory controller.

23. The memory system according to claim 18, wherein a data item is stored in one of the plurality of memory components in dependence on a voltage level of the amplified data signal.

24. A memory system, comprising:
a buffer circuit configured to buffer a data signal and supply an output data signal; and
a memory subsystem comprising a plurality of memory components, wherein each of the memory components is configured to store a data item, wherein a data item is stored in one of the plurality of memory components in dependence on a level of the output data signal.

25. The memory system according to claim 24, wherein the buffer circuit comprises an amplifier circuit, wherein the data signal is amplified by the amplifier circuit and an amplified data signal is provided at an output of the amplifier circuit.

26. A method for operating a memory module, comprising:
applying a data signal to connectors arranged on a circuit board;
transferring the data signal to at least an amplifier circuit arranged on the circuit board;
amplifying the data signal by the amplifier circuit; and
transferring the amplified data signal to at least a memory component arranged on the circuit board.

27. The method according to claim 26, further comprising:
storing a data item in the at least one memory component in dependence on a level of the received amplified data signal.

28. The method according to claim 26, further comprising:
transferring the amplified data signal to a first memory component arranged on the first surface of the circuit board and to a second memory component arranged on a second surface of the circuit board located opposite to the first surface.

29. The method according to claim 26, further comprising:
applying an address signal to connectors arranged on the circuit board;
transferring the address signal to the amplifier circuit;
amplifying the address signal by the amplifier circuit; and
transferring the amplified address signal to the at least one memory component.
